(19) United States
(12) Patent Application Publication
(10) Pub. No.: US 2012/0104441 A1
(43) Pub. Date: May 3, 2012

(54) METHOD OF MANUFACTURING COLOR FILTER SUBSTRATE, SEMI-TRANSMISSIVE LIQUID CRYSTAL DISPLAY USING THE SAME, AND MANUFACTURING METHOD THEREOF

(75) Inventor: Ji Ryun Park, Cheonan-si (KR)

(73) Assignee: Samsung Mobile Display Co., Ltd., Yongin-city (KR)

(21) Appl. No.: 13/194,651

(22) Filed: Jul. 29, 2011

(30) Foreign Application Priority Data
Oct. 29, 2010 (KR) 10-2010-0107265

(51) Int. Cl. H01L 27/15; H01L 33/50; G03F 1/10

(52) U.S. Cl. 257/98; 430/7; 438/30; 257/E33.061; 257/E27.12

(57) ABSTRACT

A manufacturing method of a color filter substrate, a semi-transmissive LCD using the same, and a manufacturing method thereof are disclosed. In one embodiment, the manufacturing method of the color filter substrate includes preparing a first substrate which comprises a reflection region and a transmission region. Then, a color resist on the first substrate is formed. A mask, including a semi-transmission mask corresponding to the reflection region, is provided on the color resist. An exposure process is provided for the color resist with the mask to form a color filter layer on the first substrate. The color filter layer is formed by removing a portion of the color resist of the reflection region.

### CROSS-REFERENCE TO RELATED APPLICATIONS

This U.S. non-provisional patent application claims priority under 35 U.S.C. §119 of Korean Patent Application No. 10-2010-0107265, filed on Oct. 29, 2010, the entire contents of which are hereby incorporated by reference.

### BACKGROUND

1. Field

The described technology generally relates to a liquid crystal display (LCD), and more particularly, to a method of manufacturing a color filter substrate, a semi-transmissive LCD using the same, and a manufacturing method thereof.

2. Description of the Related Technology

LCDs are categorized into transmissive LCDs and reflective LCDs based on the type of light source. Generally, the transmissive LCDs include a backlight unit that is disposed in the rear surface of a liquid crystal panel, and light from the backlight unit passes through the liquid crystal panel. However, the transmissive LCDs consume much power and have increased weight and thickness. The reflective LCDs have a structure that again reflects light incident from the environment. The reflective LCDs consume less power than the transmissive LCDs (e.g., about 70%). As LCDs applied to portable communication devices, particularly, the reflective LCDs are attracting much attention.

On the other hand, by making the best of the transmissive LCDs and reflective LCDs, semi-transmissive LCDs secure brightness appropriate for a use environment irrespective of the change of ambient light intensity. The semi-transmissive LCDs use a backlight unit in doors or a dark place where an external light source does not exist, and use external incident light at an indoor/outdoor high illumination environment.

### SUMMARY

One inventive aspect is a manufacturing method of a color filter substrate, a semi-transmissive liquid crystal display (LCD) having the color filter substrate, and a method of manufacturing the LCD, which enhance a color reproduction rate.

Another aspect is a method of forming a color filter substrate including: preparing a first substrate which includes a reflection region and a transmission region; forming a color resist on the first substrate; providing a mask which includes a semi-transmission mask corresponding to the reflection region, on the color resist; and performing an exposure process for the color resist with the mask to form a color filter layer on the first substrate, wherein the color filter layer is formed by removing a portion of the color resist of the reflection region.

A thickness of the color filter layer formed in the reflection region may be thinner than a thickness of the color filter layer formed in the transmission region.

An upper surface of the color filter layer formed in the reflection region may be connected to an upper surface of the color filter layer formed in the transmission region, through an inclined surface.

The semi-transmission mask may include a half-tone mask.

The semi-transmission mask may include a slit mask.

The mask may further include a light shielding mask corresponding to the transmission region.

The color resist may be a positive resist.

The color resist may be a negative resist.

Another aspect is a method of forming semi-transmissive liquid crystal display (LCD) which includes: providing a thin film transistor substrate which includes a reflection region and a transmission region; providing a color filter substrate which faces the thin film transistor substrate; forming a color filter layer in one surface of the color filter substrate facing the thin film transistor substrate; and providing liquid crystal between the thin film transistor substrate and the color filter substrate, wherein: a thickness of the color filter layer formed in the reflection region is thinner than a thickness of the color filter layer formed in the transmission region, and the thickness of the color filter layer is successively changed in a boundary between the reflection region and the transmission region.

The forming a color filter layer may include: forming a color resist on the color filter substrate; providing a mask which includes a semi-transmission mask corresponding to the reflection region and a light shielding mask corresponding to the transmission region, on the color resist; and performing an exposure process for the color resist with the mask.

The semi-transmission mask may include one of a slit mask or a half-tone mask.

Another aspect is a semi-transmissive liquid crystal display (LCD) includes: a color filter substrate including a reflection region and a transmission region; a color filter layer provided in one surface of the color filter substrate; a thin film transistor substrate facing the one surface of the color filter substrate; and a liquid crystal layer provided between the color filter substrate and the thin film transistor substrate, wherein: a thickness of the color filter layer provided in the reflection region is thinner than a thickness of the color filter layer provided in the transmission region, and the thickness of the color filter layer is successively changed in a boundary between the reflection region and the transmission region.

The semi-transmissive LCD may further include: a thin film transistor disposed on the thin film transistor substrate corresponding to the reflection region; and a reflection electrode disposed between the color filter substrate and the thin film transistor substrate provided in the reflection region.

The semi-transmissive LCD may further include: an organic layer provided between the reflection electrode and the thin film transistor.

### BRIEF DESCRIPTION OF THE DRAWINGS

FIGS. 1A to 1C are cross-sectional views illustrating a method of forming a color filter substrate according to a first embodiment.

FIGS. 2A to 2C are cross-sectional views illustrating a method of forming a color filter substrate according to a second embodiment.

FIGS. 3A to 3C are cross-sectional views illustrating a method of forming a color filter substrate according to a third embodiment.

FIGS. 4A to 4C are cross-sectional views illustrating a method of forming a color filter substrate according to a fourth embodiment.

FIG. 5 is a schematic diagram illustrating a semi-transmissive LCD using a color filter substrate which is formed according to embodiments.

### DETAILED DESCRIPTION

Embodiments will be described below in more detail with reference to the accompanying drawings.

In the specification, it will be understood that when an element is referred to as being ‘on’ another element, it can be directly on the other element, or intervening elements may also be present. Also, in the figures, the dimensions of layers and regions may be exaggerated for clarity of illustration. Like reference numerals refer to like elements throughout.

In the figures, the dimensions of layers and regions may be exaggerated for clarity of illustration. Accordingly, shapes of elements/devices may be modified according to manufacturing techniques and/or allowable errors. Therefore, the disclosed embodiments are not limited to the specific shape illustrated in the drawings, but may include other shapes that may be created according to manufacturing processes. Also, though terms like a first, a second, and a third are used to describe various regions and layers in various embodiments, the regions and the layers are not limited to these terms. These terms are used only to distinguish one region or layer from another region or layer.

The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

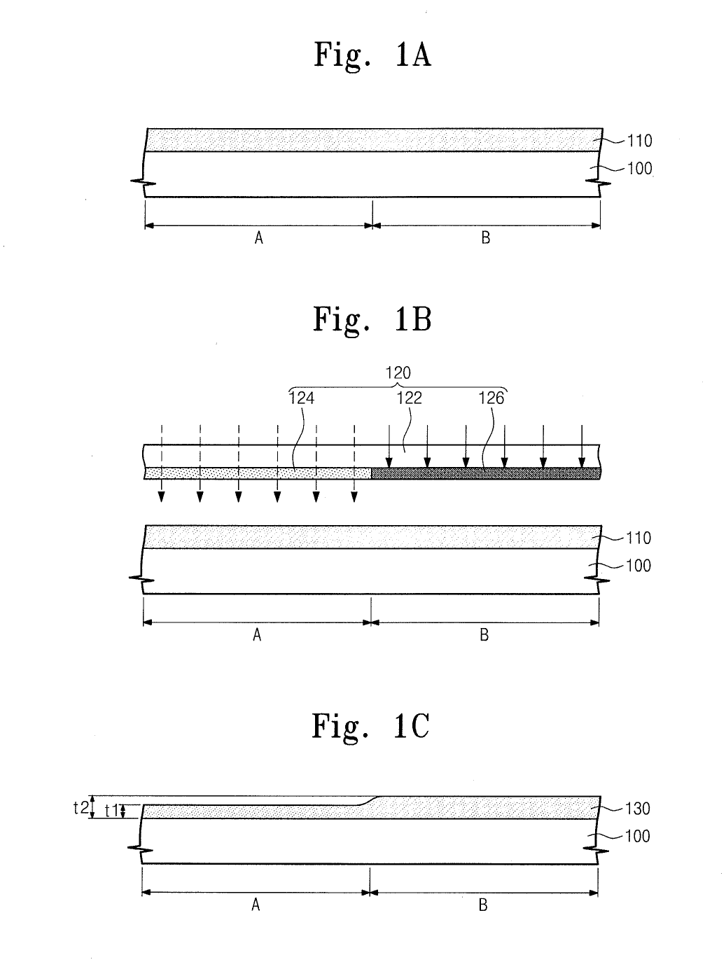

FIGS. 1A to 1C are cross-sectional views illustrating a method of forming a color filter substrate according to a first embodiment.

Referring to FIG. 1A, a first substrate 100 including a reflection region A and a transmission region B is prepared. The first substrate 100 may include a glass substrate. The reflection region A substantially corresponds to a region using light incident from the environment, and the transmission region B substantially corresponds to a region in which light from the backlight unit passes through a liquid crystal panel.

A color resist 110 is formed on the first substrate 100. A black matrix (not shown) may be formed before the color resist 110 is formed. The black matrix may be formed of chromium oxide or chromium (Cr) in a sputtering process. Alternatively, the black matrix may be formed by doping a carbon-based organic material and patterning an organic layer.

The color resist 110 may be formed of a material containing a pigment for realizing color. The color resist 110 may be formed in a spin coating process, i.e., by spilling a certain amount of resist on the first substrate 100 and rotating the first substrate 100 at a high speed. Alternatively, the color resist 110 may be formed of a roll coat process, i.e., by transferring or printing a resist, which is evolved on a roll, on the first substrate 100.

Referring to FIG. 1B, a mask 120 is provided on the color resist 110. The mask 120 includes a transparent substrate 122, a semi-transmission mask 124 formed in one surface of the transparent substrate 122, and a light shielding mask 126 formed in the other surface of the transparent substrate 122. The semi-transmission mask 124 may be substantially aligned in correspondence with the reflection region A, and the light shielding mask 126 may be substantially aligned in correspondence with the transmission region B.

The semi-transmission mask 124 may include a half-tone mask. The semi-transmission mask 124 may be about 50% light transmittance. The light shielding mask 126 may be about 0% light transmittance because it shields light. An exposure process is performed for the color resist 110 with the mask 120. The color resist 110 may be a positive resist.

Referring to FIG. 1C, a color filter layer 130 is formed on the first substrate 100. The thickness t1 of the color filter layer 130 formed in the reflection region A may be thinner than the thickness t2 of the color filter layer 130 formed in the transmission region B. For example, the thickness t2 may be about two times greater than the thickness t1.

The upper surface of the color filter layer 130 formed in the reflection region A may be connected to the upper surface of the color filter layer 130 formed in the reflection region B, through an inclined surface. That is, the upper surface of the color filter layer 130 formed in the reflection region A may be connected to the upper surface of the color filter layer 130 formed in the reflection region B without a jump of a height in an area corresponding to an area between the reflection region A and the transmission region B. This is because an exposure process is performed with the one mask 120 and the color resist 110 is developed. Alternatively, it may be understood that the upper surface of the color filter layer 130 formed in the reflection region A is successively extended to the upper surface of the color filter layer 130 formed in the reflection region B.

According to a first embodiment, the thickness of the color filter layer 130 formed in the reflection region A is thinner than that of the color filter layer 130 formed in the reflection region B. Also, the color filter layer 130 of the reflection region A and transmission region B is formed with the one mask 120, and thus a sudden change of height cannot be formed in the color filter layer 130. The above structure is advantageous because if each color filter layer is formed using different masks, a jump of a height in an area corresponding to an area between the reflection region A and the transmission region B may occur.

The thickness of the color filter layer 130 formed in the reflection region A differs from the thickness of the color filter layer 130 formed in the reflection region B, and thus a color difference between a reflection mode and a transmission mode can be minimized. Accordingly, the semi-transmissive LCD can enhance a color reproduction rate.

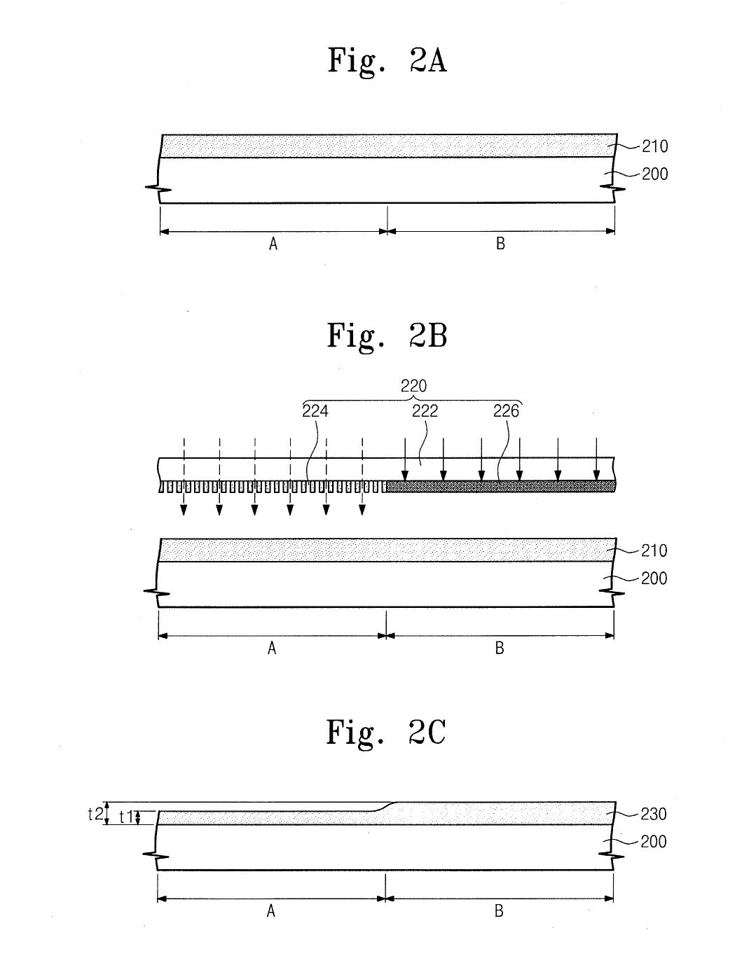

FIGS. 2A to 2C are cross-sectional views illustrating a method of forming a color filter substrate according to a second embodiment. For conciseness, repetitive description on the same technical content as that of FIGS. 1A to 1C will be omitted.

Referring to FIG. 2A, a first substrate 200 including a reflection region A and a transmission region B is prepared. The first substrate 200 may include a glass substrate. The reflection region A substantially corresponds to a region using light incident from the outside, and the transmission region B substantially corresponds to a region in which light from the backlight unit passes through a liquid crystal panel.

A color resist 210 is formed on the first substrate 200. A black matrix (not shown) may be formed before the color resist 210 is formed. The color resist 210 may be formed of a material containing a pigment for realizing color.

Referring to FIG. 2B, a mask 220 is provided on the color resist 210. The mask 220 includes a transparent substrate 222, a semi-transmission mask 224 formed in one surface of the transparent substrate 222, and a light shielding mask 226 formed in the other surface of the transparent substrate 222. The semi-transmission mask 224 may be substantially aligned in correspondence with the reflection region A, and the light shielding mask 226 may be substantially aligned in correspondence with the transmission region B.

The semi-transmissive mask 224 may include a slit mask. The semi-transmission mask 224 may be about 50% light transmittance. The light shielding mask 226 may be about 0% light transmittance. An exposure process is performed for the color resist 210 with the mask 220. The color resist 210 may be a positive resist.

Referring to FIG. 2C, a color filter layer 230 is formed on the first substrate 200. The thickness t1 of the color filter layer 230 formed in the reflection region A may be thinner than the thickness t2 of the color filter layer 230 formed in the transmission region B. For example, the thickness t2 may be about two times greater than the thickness t1.

The upper surface of the color filter layer 230 formed in the reflection region A may be connected to the upper surface of the color filter layer 230 formed in the reflection region B, through an inclined surface. That is, the upper surface of the color filter layer 230 formed in the reflection region A may be connected to the upper surface of the color filter layer 230 formed in the reflection region B without a jump of height in an area corresponding to an area between the reflection region A and the transmission region B. This is because an exposure process is performed with the one mask 220 and the color resist 210 is developed. Alternatively, it may be understood that the upper surface of the color filter layer 230 formed in the reflection region A is successively extended to the upper surface of the color filter layer 230 formed in the reflection region B.

According to a second embodiment, the color filter layer 230 is formed with the slit mask. The thickness of the color filter layer 230 formed in the reflection region A is thinner than that of the color filter layer 230 formed in the reflection region B. Also, the color filter layer 230 of the reflection region A and transmission region B is formed with the one mask 220, and thus a sudden change of height cannot be formed in the color filter layer 230.

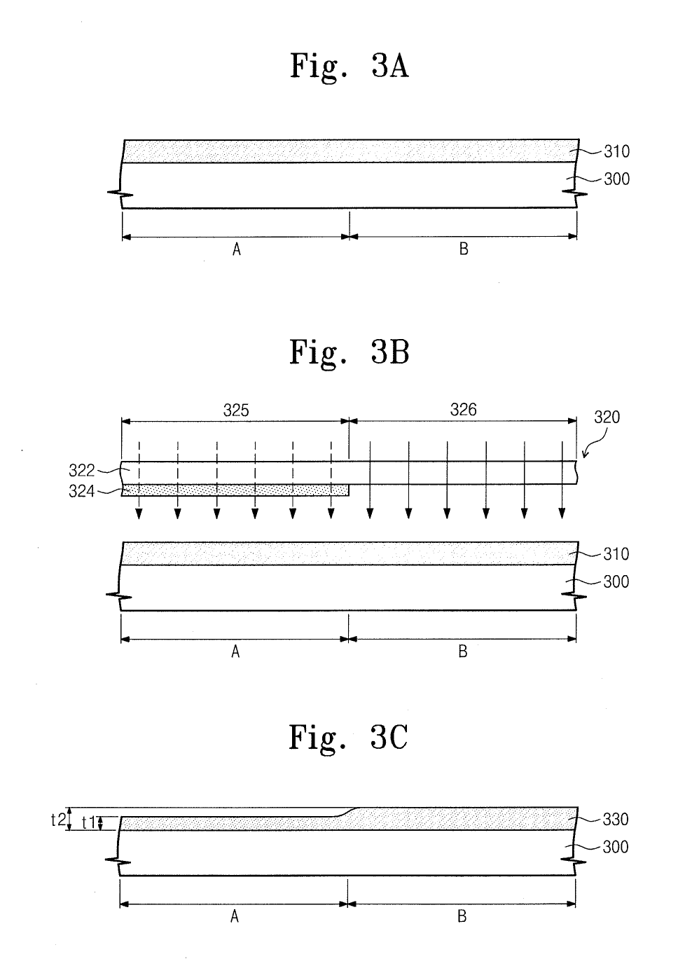

FIGS. 3A to 3C are cross-sectional views illustrating a method of forming a color filter substrate according to a third embodiment. For conciseness, repetitive description on the same technical content as that of FIGS. 1A to 1C will be omitted.

Referring to FIG. 3A, a first substrate 300 including a reflection region A and a transmission region B is prepared. The first substrate 300 may include a glass substrate. The reflection region A substantially corresponds to a region using light incident from the outside, and the transmission region B substantially corresponds to a region in which light from the backlight unit passes through a liquid crystal panel.

A color resist 310 is formed on the first substrate 300. A black matrix (not shown) may be formed before the color resist 310 is formed. The color resist 310 may be formed of a material containing a pigment for realizing color.

Referring to FIG. 3B, a mask 320 is provided on the color resist 310.

The mask 320 includes a semi-transmission mask 325 and a transmission region mask 326. The semi-transmission mask 325 may be substantially aligned in correspondence with the reflection region A, and the transmission region mask 326 may be substantially aligned in correspondence with the transmission region B.

The semi-transmissive mask 325 may include a half-tone mask 324 that is formed in one surface of the transparent substrate 322. The semi-transmission mask 325 may be about 50% light transmittance. The transmission region mask 326 may include a transmission mask that transmits light. The transmission region mask 326 may be formed as only the transparent substrate 322. The transmission region mask 326 may be about 100% light transmittance. An exposure process is performed for the color resist 310 with the mask 320. The color resist 310 may be a negative resist.

Referring to FIG. 3C, a color filter layer 330 is formed on the first substrate 300. The thickness t1 of the color filter layer 330 formed in the reflection region A may be thinner than the thickness t2 of the color filter layer 330 formed in the transmission region B. For example, the thickness t2 may be about two times greater than the thickness t1.

The upper surface of the color filter layer 330 formed in the reflection region A may be connected to the upper surface of the color filter layer 330 formed in the reflection region B, through an inclined surface. That is, the upper surface of the color filter layer 330 formed in the reflection region A may be connected to the upper surface of the color filter layer 330 formed in the reflection region B without a jump of height in an area corresponding to an area between the reflection region A and the transmission region B. This is because an exposure process is performed with the one mask 320 and the color resist 310 is developed. Alternatively, it may be understood that the upper surface of the color filter layer 330 formed in the reflection region A is successively extended to the upper surface of the color filter layer 330 formed in the reflection region B.

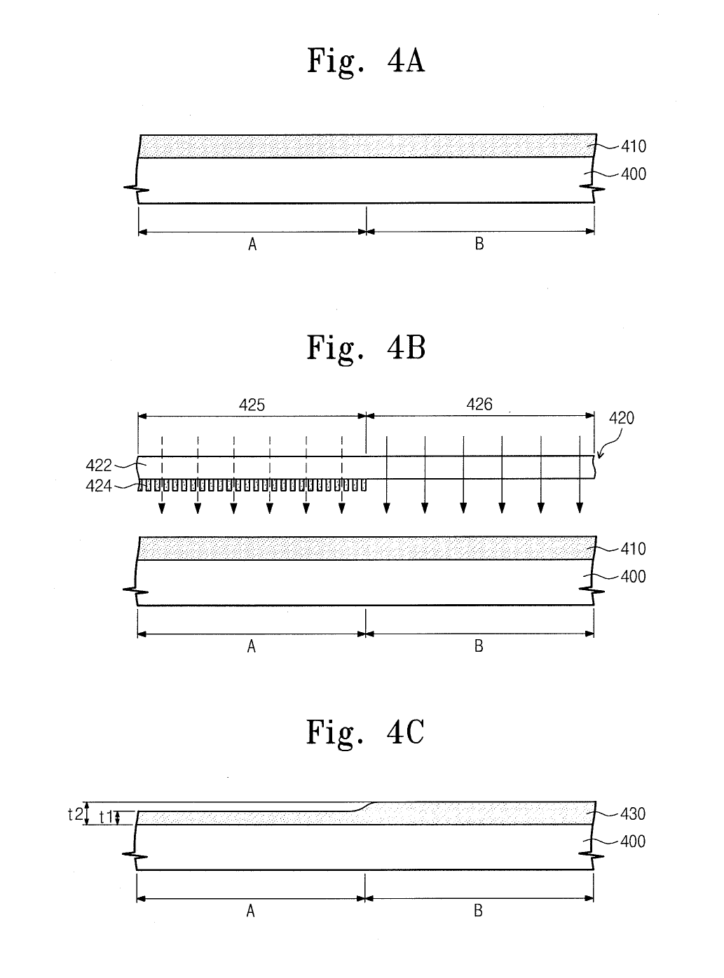

FIGS. 4A to 4C are cross-sectional views illustrating a method of forming a color filter substrate according to a fourth embodiment. For conciseness, repetitive description on the same technical content as that of FIGS. 1A to 1C will be omitted.

Referring to FIG. 4A, a first substrate 400 including a reflection region A and a transmission region B is prepared. The first substrate 400 may include a glass substrate. The reflection region A substantially corresponds to a region using light incident from the outside, and the transmission region B substantially corresponds to a region in which light from the backlight unit passes through a liquid crystal panel.

A color resist 410 is formed on the first substrate 400. A black matrix (not shown) may be formed before the color resist 410 is formed. The color resist 410 may be formed of a material containing a pigment for realizing color.

Referring to FIG. 4B, a mask 420 is provided on the color resist 410. The mask 420 includes a semi-transmission mask 425 and a transmission region mask 426. The semi-transmission mask 425 may be substantially aligned in correspondence with the reflection region A, and the transmission region mask 426 may be substantially aligned in correspondence with the transmission region B.

The semi-transmissive mask 425 may include a slit mask 424 that is formed in one surface of the transparent substrate 422. The semi-transmission mask 425 may be about 50% light transmittance. The transmission region mask 426 may include a transmission mask that transmits light. The transmission region mask 426 may be formed as only the transparent substrate 422. The transmission region mask 426 may be about 100% light transmittance. An exposure process is performed for the color resist 410 with the mask 420. The color resist 410 may be a negative resist.

Referring to FIG. 4C, a color filter layer 430 is formed on the first substrate 400. The thickness t1 of the color filter layer 430 formed in the reflection region A may be thinner than the thickness t2 of the color filter layer 430 formed in the transmission region B. For example, the thickness t2 may be about two times greater than the thickness t1.

The upper surface of the color filter layer 430 formed in the reflection region A may be connected to the upper surface of the color filter layer 430 formed in the reflection region B, through an inclined surface. That is, the upper surface of the color filter layer 430 formed in the reflection region A may be connected to the upper surface of the color filter layer 430 formed in the reflection region B without a sudden change of a height difference. This is because an exposure process is performed with the one mask 420 and the color resist 410 is developed. Alternatively, it may be understood that the upper surface of the color filter layer 430 formed in the reflection region A is successively extended to the upper surface of the color filter layer 430 formed in the reflection region B.

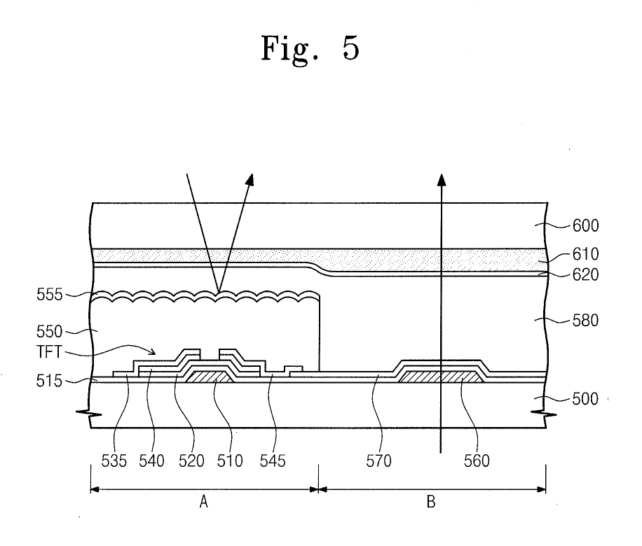

FIG. 5 is a schematic diagram illustrating a semi-transmissive LCD using a color filter substrate which is formed according to embodiments.

Referring to FIG. 5, a thin film transistor substrate 500 including a reflection region A and a transmission region B is prepared. A thin film transistor TFT is disposed on the thin film transistor substrate 500 of the reflection region A. The thin film transistor TFT includes a gate electrode 510, a gate dielectric 515 on the gate electrode 510, a channel layer 520 on the gate dielectric 515, and a source electrode 535 and a drain electrode 545 on the channel layer 520.

The gate electrode 510 may include a metal material such as Cr. The gate dielectric 515 may include silicon nitride. The channel layer 520 may include a semiconductor material, for example, amorphous silicon. The source electrode 535 and the drain electrode 545 may include a metal material such as Cr. An ohmic contact layer 540, which is formed of, for example, amorphous silicon including an N-type dopant, may be disposed between the source electrode 535 and the channel layer 520, and between the drain electrode 545 and the channel layer 520. An organic layer 550 covering the thin film transistor TFT is provided, and a reflection electrode 555 is disposed on the organic layer 550. The reflection electrode 555 may include a conductive material which reflects external light and has an excellent reflection rate.

A storage electrode 560 is disposed on the thin film transistor substrate 500 of the transmission region B. The storage electrode 560 may include a metal material such as Cr. The gate dielectric 515 of the reflection region A is extended and covers the storage electrode 560. A pixel electrode 570 electrically connected to the drain electrode 545 is disposed on the gate dielectric 515 of the transmission region B. The pixel electrode 570 may include indium tin oxide (ITO) for transmitting light.

A color filter substrate 600 is disposed to face the thin film transistor substrate 500. A color filter layer 610 is disposed on one surface of the color filter substrate 600 facing the thin film transistor substrate 500. The thickness of the color filter layer 610 provided in the reflection region A may be thinner than that of the color filter layer 610 provided in the transmission region B. For example, the thickness of the color filter layer 610 provided in the transmission region B may be approximately two times greater than the thickness of the color filter layer 610 provided in the reflection region A. The thickness of the color filter layer 610 may be successively changed or substantially gradually change in a boundary between the reflection region A and the transmission region B. Alternatively, it may be understood that the color filter layer 610 of the reflection region A is connected to the color filter layer 610 of the transmission region B through an inclined surface.

A common electrode 620 covering the color filter layer 610 is disposed. The common electrode 620 may include ITO. A liquid crystal layer 580 is provided between the thin film transistor substrate 500 and the color filter substrate 600.

According to one embodiment, since the thickness of the color filter layer 610 in the reflection region A is thinner than that of the color filter layer 610 in the transmission region B, a color difference between the reflection region A and the transmission region B can be minimized. Specifically, when the thickness of the color filter layer 610 provided in the transmission region B may be approximately two times greater than the thickness of the color filter layer 610 provided in the reflection region A, a distance in which external light is reflected by the reflection region A and then passes through the color filter layer 610 may be substantially the same as a distance in which light from the backlight unit (not shown) passes through the color filter layer 610.

According to at least one of the disclosed embodiments, the thickness of the color filter layer formed in the reflection region is thinner than that of the color filter layer formed in the transmission region. Moreover, the color filter layer of the reflection region and the color filter of the transmission region are formed with one mask, and thus the thicknesses of the color filter layers can be continuously changed in the boundary between the reflection region and the transmission region.

By differently forming the thicknesses of the color filter layers that are respectively formed in the reflection region and the transmission region, the color difference between the reflection mode and the transmission mode can be minimized. Accordingly, the semi-transmissive LCD can enhance a color reproduction rate.

The above-disclosed subject matter is to be considered illustrative and not restrictive, and the appended claims are intended to cover all such modifications, enhancements, and other embodiments.

What is claimed is:

1. A method of manufacturing a color filter substrate, the method comprising:
preparing a first substrate which comprises a reflection region and a transmission region;
forming a color resist on the first substrate;
providing a mask which comprises a semi-transmission mask substantially corresponding to the reflection region, on the color resist; and
performing an exposure process for the color resist with the mask to form a color filter layer on the first substrate,
wherein the color filter layer is formed by removing a portion of the color resist of the reflection region.

2. The method of claim 1, wherein the thickness of the color filter layer formed in the reflection region is thinner than the thickness of the color filter layer formed in the transmission region.

3. The method of claim 2, wherein an upper surface of the color filter layer formed in the reflection region is connected to an upper surface of the color filter layer formed in the transmission region, through an inclined surface.

4. The method of claim 1, wherein the semi-transmission mask comprises a half-tone mask.

5. The method of claim 1, wherein the semi-transmission mask comprises a slit mask.

6. The method of claim 1, wherein the mask further comprises a light shielding mask substantially corresponding to the transmission region.

7. The method of claim 6, wherein the color resist is a positive resist.

8. The method of claim 1, wherein the color resist is a negative resist.

9. A method of manufacturing semi-transmissive liquid crystal display (LCD), the method comprising:
providing a thin film transistor substrate which comprises a reflection region and a transmission region;
providing a color filter substrate so as to face the thin film transistor substrate;
forming a color filter layer in one surface of the color filter substrate; and
providing a liquid crystal layer between the thin film transistor substrate and the color filter substrate,
wherein the thickness of the color filter layer formed in the reflection region is thinner than the thickness of the color filter layer formed in the transmission region, and wherein the thickness of the color filter layer substantially gradually changes in a boundary between the reflection region and the transmission region.

10. The method of claim 9, wherein the forming a color filter layer comprises:
forming a color resist on the color filter substrate;
providing a mask which comprises a semi-transmission mask substantially corresponding to the reflection region and a light shielding mask substantially corresponding to the transmission region, on the color resist; and
performing an exposure process for the color resist with the mask.

11. The method of claim 10, wherein the semi-transmission mask comprises a slit mask or a half-tone mask.

12. A semi-transmissive liquid crystal display (LCD) comprising:
a color filter substrate comprising a reflection region and a transmission region;
a color filter layer provided in a surface of the color filter substrate;
a thin film transistor substrate facing the surface of the color filter substrate; and
a liquid crystal layer provided between the color filter substrate and the thin film transistor substrate,
wherein the thickness of the color filter layer provided in the reflection region is thinner than the thickness of the color filter layer provided in the transmission region, and wherein the thickness of the color filter layer substantially gradually changes in a boundary between the reflection region and the transmission region.

13. The semi-transmissive LCD of claim 12, further comprising:
a thin film transistor disposed on the thin film transistor substrate corresponding to the reflection region; and
a reflection electrode disposed between the color filter substrate and the thin film transistor substrate provided in the reflection region.

14. The semi-transmissive LCD of claim 13, further comprising: an organic layer provided between the reflection electrode and the thin film transistor.
